(19) United States
(12) Patent Application Publication
(10) Pub. No.: US 2025/0349622 A1
(43) Pub. Date: Nov. 13, 2025

(54) DEFECT DETECTION DEVICE OF WAFER AND CHIP PACKAGING AND DETECTING METHOD OF DEFECT OF WAFER AND CHIP PACKAGING

(71) Applicants: KUN-HSIEN CHENG, Taoyuan City (TW); SHYAWEI OPTRONICS CORPORATION CO., LTD., Taoyuan City (TW)

(72) Inventor: KUN-HSIEN CHENG, Taoyuan City (TW)

(21) Appl. No.: 19/198,434

(22) Filed: May 5, 2025

(30) Foreign Application Priority Data
May 8, 2024 (TW) 113116944
Aug. 5, 2024 (TW) 113129252

(51) Int. Cl. H01L 21/66; G01N 29/06

(52) U.S. Cl. CPC H01L 22/12; G01N 29/0654; G01N 2291/0231; G01N 2291/0289; G01N 2291/2697

(57) ABSTRACT

A detecting method of defects of wafer and chip packaging for detecting the first defect (such as, bubble defect) in an object includes: disposing an antistatic film on a contact surface of the object, wherein an area of the antistatic film is larger than an area of the object, so that the antistatic film completely covers the contact surface of the object, the object has a plurality of layer structures, and the plurality of the layer structures have the first defect between the two layer structures; disposing a conductive liquid on an upper surface of the antistatic film facing away from the object; and disposing an ultrasonic detector into the conductive liquid to detect the first defect located in the object, wherein an end portion of the ultrasonic detector is covered with the conductive liquid, and the end portion is separated from the upper surface of the antistatic film.

### CROSS REFERENCE TO RELATED APPLICATIONS

The present patent application claims foreign priority of TW application Ser. No. 11/312,9252 filed on Aug. 5, 2025 under 35 U.S.C. § 119 and TW application Ser. No. 11/311,6944 filed on May 8, 2025, under 35 U.S.C. § 119, wherein all contents of the reference which priority is claimed by the present patent application are included in the present patent application, herein.

### TECHNICAL FIELD

The present disclosure relates to a detection device and a detection method, particularly a defect detection device of wafer and chip packaging and a method for detecting defects of wafer and chip packaging.

### BACKGROUND

Generally, when wafers or substrates are stacked, gaps are likely to form between the stacked layers, and these gaps are regarded as bubble defects. These bubble defects reduce the electrical conductivity of the final product when the stacked wafers or substrates are processed into a product, thereby affecting the product yield. Therefore, developing a detection device and method capable of instantly detecting bubble defects in multilayer stacked structures is a key research objective for a person ordinarily skilled in the art in the field. Additionally, some stacked wafer or chip structures cannot come into contact with detection liquids, or the drying and cleaning process after contact with the detection liquid may damage the stacked structure or introduce other impurities into the wafer or chip. This further increases the complexity and duration of the bubble detection process for wafer and chip packaging. Furthermore, in addition to the bubble defect, there are other defects existed in multilayer stacked structures.

### SUMMARY

One aspect of the present disclosure provides a method for detecting defects of wafer and chip packaging. This method may detect defects in an object and provide real-time feedback to operators to improve the yield of subsequent product manufacturing.

An embodiment of the present disclosure provides a method for detecting defects of wafer and chip packaging. This method is used to detect a first defect in an object. The detection method includes: disposing a transparent or translucent antistatic film on a contact surface of the object, wherein an area of the antistatic film is larger than an area of the object so that the antistatic film completely covers the contact surface of the object. The object has a plurality of layer structures, and the plurality layer structures have the first defect between two adjacent upper- and lower-layer structures, wherein the first defect is detectable to an ultrasonic detector. The method further includes applying a conductive liquid on an upper surface of the antistatic film that is facing away from the object, and placing the ultrasonic detector into the conductive liquid to detect the first defect located in the object, wherein an end portion of the ultrasonic detector is covered by the conductive liquid and the end portion is separated from the upper surface of the antistatic film.

According to one embodiment of the method of the present disclosure, detecting the first defect in the object further includes: scanning the contact surface of the object below the antistatic film with the ultrasonic detector in a reciprocating manner to generate a first detection image including the first defect; and transmitting the first detection image to a determining module.

According to one embodiment of the method of the present disclosure, the first defect is a bubble defect, a dirty defect, a impurity defect or a crack defect.

According to one embodiment of the method of the present disclosure, the detection method further includes: positioning a camera above the upper surface of the antistatic film; using the camera to observe a second defect to generate a second detection image including the second defect, wherein the second defect is located between the lower surface of the antistatic film and the contact surface of the object; and transmitting the second detection image to the determining module that stores the first detection image.

According to one embodiment of the method of the present disclosure, the first defect is a first bubble defect and the second defect is a second bubble defect.

According to one embodiment of the method of the present disclosure, the detection method further includes: the determining module subtracting the second detection image from the first detection image to obtain a third detection image, and the determining module determining the shape and position of the first defect based on the third detection image, wherein the second defect is a defect visible to the camera and detectable to the ultrasonic detector.

According to one embodiment of the method of the present disclosure, the detection method further includes: using a hollow annular barrier of the antistatic film to restrict the conductive liquid, so that the conductive liquid is confined within a detection area defined by the hollow annular barrier.

Another aspect of the present disclosure provides a defect detection device of wafer and chip packaging, which may also detect defects in an object and provide real-time feedback to operators to improve the yield of subsequent product manufacturing.

An embodiment of the present disclosure provides a detection device for wafer and chip packaging. This defect detection device is used to detect the first defect in an object. The device includes a platform, a film attaching component, a liquid infusion component, and an ultrasonic detector. The platform is for placing the object. The object has a plurality of layer structures. The plurality of the layer structures has the first defect between two adjacent upper and lower layer structures, and the first defect is detectable to the ultrasonic detector. The film attaching component is disposed above the platform and is used for placing a transparent or translucent antistatic film on the contact surface of the object. The area of the antistatic film is larger than that of the object, so that the antistatic film completely covers the contact surface of the object. The liquid infusion component is disposed above the antistatic film and is used for applying a conductive liquid on an upper surface of the antistatic film that is facing away from the object. The ultrasonic detector is disposed above the object and is placed into the conductive liquid to detect the first defect located in the object. The end of the ultrasonic detector is covered with the conductive liquid and is separated from the upper surface of the antistatic film.

According to one embodiment of the detection device of the present disclosure, the object is a wafer-on-wafer (WoW) structure, a chip-on-wafer (CoW) structure, or a substrate-on-substrate structure.

According to one embodiment of the detection device of the present disclosure, the ultrasonic detector is further used to scan the contact surface of the object below the antistatic film in a reciprocating manner to generate a first detection image including the first defect.

According to one embodiment of the detection device of the present disclosure, the first defect is a bubble defect, a dirty defect, a impurity defect or a crack defect.

According to one embodiment of the detection device of the present disclosure, the detection device of wafer and chip packaging further includes a camera and a determining module. The camera is disposed above the antistatic film and is used for observing a second defect to generate a second detection image including the second defect. The second defect is located between the lower surface of the antistatic film and the contact surface of the object. The determining module is electrically coupled to the camera and the ultrasonic detector and is used for receiving the first detection image and the second detection image.

According to one embodiment of the detection device of the present disclosure, the first defect is a bubble defect, a dirty defect, a impurity defect or a crack defect.

According to one embodiment of the detection device of the present disclosure, the determining module is further used for subtracting the second detection image from the first detection image to obtain a third detection image. The determining module then determines the shape and position of the first defect based on the third detection image, wherein the second defect is a defect visible to the camera and detectable to the ultrasonic detector.

According to one embodiment of the detection device of the present disclosure, the antistatic film has a hollow annular barrier to restrict the conductive liquid, so that the conductive liquid is confined within a detection area defined by the hollow annular barrier.

In the above embodiment of the present disclosure, the ultrasonic detector of the defect detection device of wafer and chip packaging may transmit the first detection image to the determining module. The determining module may determine the shape and position of the first defect in the object by analyzing both the first and second detection images. After obtaining the shape and position of the first defect, the device may immediately notify the operator the shape and position of the first defect. During subsequent processing, the part of the object corresponding to the first defect may be discarded. If the number or size of the first defects is too large, the plurality of layer structures of the object may be re-bounded. By using the defect detection device and method of the present disclosure, the product yield of multi-layer stacked structures such as wafer-on-wafer (WoW) structures, chip-on-wafer (CoW) structures, or substrate-on-substrate structures can be effectively improved.

### BRIEF DESCRIPTION OF DRAWINGS

When read in conjunction with the accompanying drawings, the following detailed description provides the best understanding of an embodiment of the present disclosure. It should be emphasized that, in accordance with industry-standard practices, various features are not drawn to scale and are used for illustrative purposes only. In fact, to clarify the discussion, the sizes of various features may be increased or decreased arbitrarily.

FIG. 1 illustrates a block diagram of a defect detection device of wafer and chip packaging according to an embodiment of the present disclosure.

FIG. 2 illustrates a flowchart of a method for detecting defects of wafer and chip packaging according to an embodiment of the present disclosure.

FIG. 3 illustrates schematic diagrams of a method for detecting defects of wafer and chip packaging at one of different stages according to some embodiments of the present disclosure.

FIG. 4 illustrates schematic diagrams of a method for detecting defects of wafer and chip packaging at one of different stages according to some embodiments of the present disclosure.

FIG. 5 illustrates a top view of the object and the antistatic film at an intermediate stage according to an embodiment of the present disclosure.

FIG. 6 illustrates schematic diagrams of a method for detecting defects of wafer and chip packaging at one of different stages according to some embodiments of the present disclosure.

FIG. 7 illustrates schematic diagrams of a method for detecting defects of wafer and chip packaging at one of different stages according to some embodiments of the present disclosure.

FIG. 8 illustrates a schematic diagram of a first detection image according to an embodiment of the present disclosure.

FIG. 9 illustrates a schematic diagram of a second detection image according to an embodiment of the present disclosure.

FIG. 10 illustrates a schematic diagram of a third detection image according to an embodiment of the present disclosure.

### DETAILS OF EXEMPLARY EMBODIMENTS

The embodiments disclosed below provide various different implementations or examples for realizing the disclosed subject matter. Specific examples of components and arrangements are described below to simplify the disclosure. These examples are merely illustrative and are not intended to be limiting. Furthermore, component numerals and/or letters may be repeated across different embodiments in this disclosure. The repetition is for convenience and clarity, and it does not, by itself, specify relationships between the various embodiments and/or configurations discussed.

Spatially relative terms such as “below,” “under,” “lower,” “above,” “upper,” and the like may be used herein for convenience of description to describe the relationship of one element or feature to another element or feature as illustrated in the drawings. The spatially relative terms are intended to cover different orientations of the device in use or operation beyond the orientation shown in the drawings. The device may be oriented differently (e.g., rotated 90 degrees or in other directions), and the spatial relative terms used herein should be interpreted accordingly.

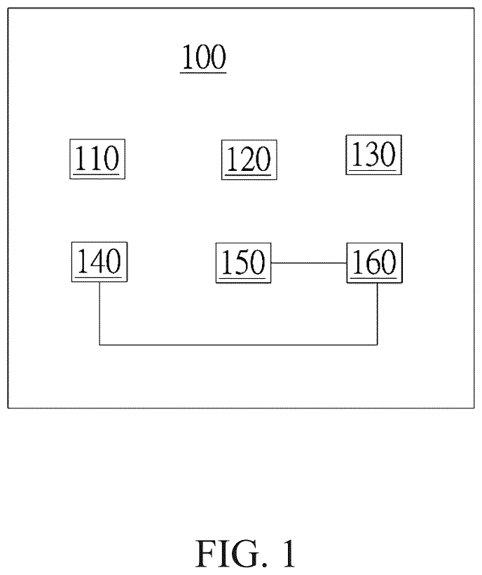

Referring to FIG. 1, FIG. 1 illustrates a block diagram of a defect detection device 100 of wafer and chip packaging according to an embodiment of the present disclosure. In FIG. 1, the defect detection device 100 of wafer and chip packaging may be used to detect defects formed in the structure of stacked wafers or chips. The defect detection device 100 includes a platform 110, a film attaching component 120, a liquid infusion component 130, a camera 140, an ultrasonic detector 150, and a determining module 160. The film attaching component 120, the liquid infusion component 130, and the ultrasonic detector 150 are disposed on one side of the platform 110, specifically, the film attaching component 120, the liquid infusion component 130, and the ultrasonic detector 150 are disposed above the platform 110. The determining module 160 is electrically coupled to the camera 140 and the ultrasonic detector 150. In addition, the determining module 160 may receive image data transmitted from the camera 140 and the ultrasonic detector 150.

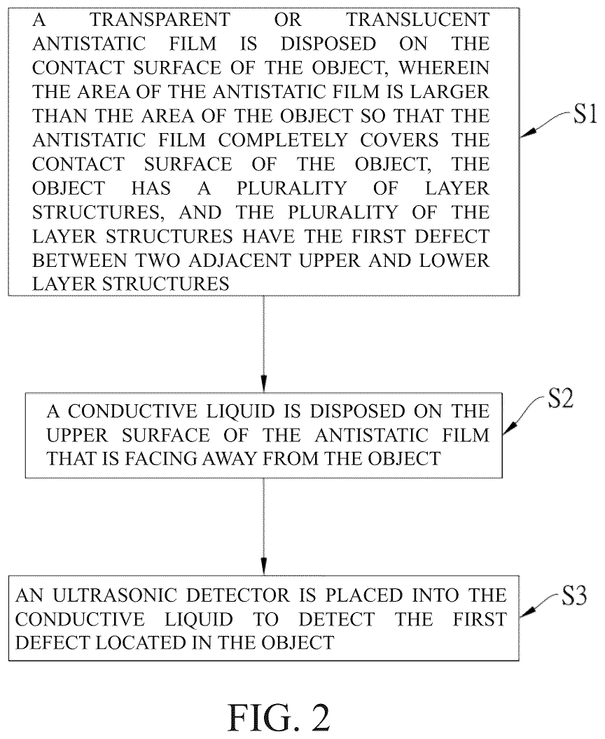

Refer to FIG. 2, and FIG. 2 illustrates a flowchart of a method for detecting defects of wafer and chip packaging according to an embodiment of the present disclosure. In FIG. 2, the method for detecting defects of wafer and chip packaging may detect the first defect in an object. For example, the object may be a stacked package of plurality wafers or plurality chips, such as, a 3D or 2.5D package chip, or High-Bandwidth Memory (HBM), and the present disclosure is not limited thereto. The method for detecting defects of wafer and chip packaging includes the following steps. First, in step S1, a transparent or translucent antistatic film is disposed on the contact surface of the object, wherein the area of the antistatic film is larger than the area of the object so that the antistatic film completely covers the contact surface of the object. The object has a plurality of layer structures, and the plurality of the layer structures have the first defect between two adjacent upper and lower layer structures, wherein the first defect is detectable to an ultrasonic detector, and can be a bubble defect, a dirty defect, a impurity defect or a crack defect. Next, in step S2, a conductive liquid is disposed on the upper surface of the antistatic film that is facing away from the object. Then, in step S3, an ultrasonic detector is placed into the conductive liquid to detect the first defect located in the object, wherein an end portion of the ultrasonic detector is covered with the conductive liquid and the end is separated from the upper surface of the antistatic film. The following descriptions will provide detailed explanations of each step.

It should be noted that the conductive liquid may be a liquid with good ultrasonic conductivity, such as water or commercially available ultrasonic transmission gel. The commonly available ultrasonic transmission gel may be a gel composed of purified water, acrylic polymers, hydroxyethyl cellulose, glycerin, preservatives, and sodium hydroxide. The antistatic film is a film with antistatic properties, such as an antistatic film made of polyethylene terephthalate (PET) material, which may have a thickness of less than 16 micrometers (16 μm) and an antistatic resistance value ranging from 10⁴ to 10¹⁰ ohms (Ω). The PET-based antistatic film is formed by coating an antistatic agent onto a PET substrate. The antistatic agent is usually a type of surfactant and may be composed of at least one of ammonium salts, quaternary ammonium salts, alkyl imidazolines, alkyl imidazolinium salts, alkyl sulfonates, phosphate esters, phosphates, alkyl dihydroxy ethyl ammonium betaines, and N-alkyl amino acid salts. It should be noted that the types of conductive liquids and antistatic films mentioned above are merely examples and are not intended to limit the present disclosure.

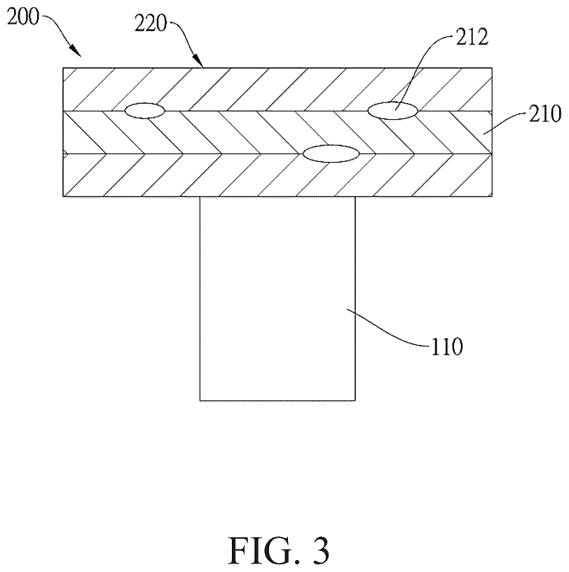

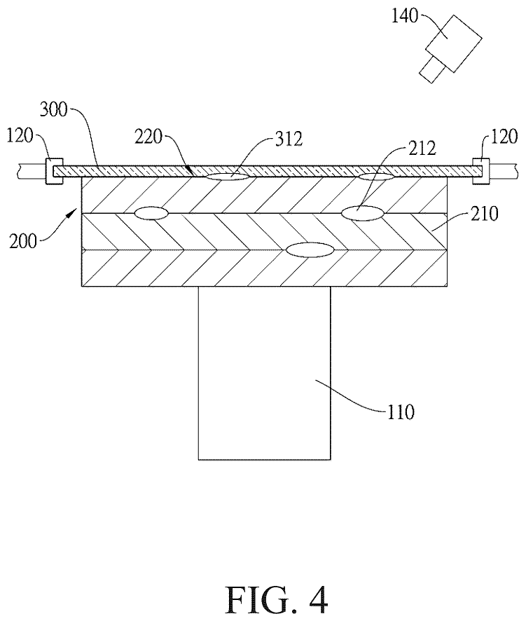

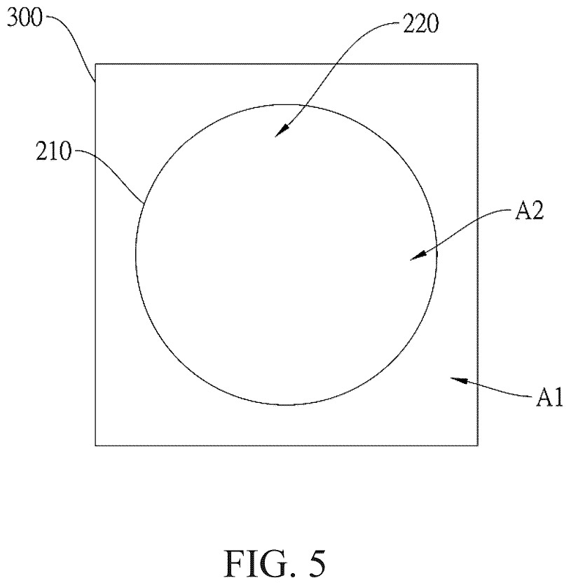

Referring to FIGS. 3 to 7, FIGS. 3, 4, 6, and 7 illustrate schematic diagrams of a method for detecting defects of wafer and chip packaging at different stages according to some embodiments of the present disclosure. FIG. 5 illustrates a top view of the object and the antistatic film at an intermediate stage according to an embodiment of the present disclosure. In FIGS. 3 to 5, first, the platform 110 may support the object 200. The object 200 may be a wafer-on-wafer (WoW) structure, a chip-on-wafer (CoW) structure, or a substrate-on-substrate structure. The object 200 has plurality layer structures. For example, the object 200 shown in FIG. 3 may have a three-layer structure 210, but the number of layers in the object 200 is not limited to this and may be two layers or more than three layers. Notably, a first defect 212 exists between adjacent upper and lower layers of the layer structure 210 of the object 200, and in the embodiment, the first defect is the bubble defect. The bubble defect is caused by gaps that easily form between the contact surfaces of the layer structures 210 while being stacked. The first defect 212 is generated as a result of the gaps formed when the layer structures 210 are stacked.

After disposing the object 200 on the platform 110, a transparent or translucent antistatic film 300 may be disposed on the contact surface 220 of the object 200 using the film attaching component 120. As shown in FIG. 5, the area A1 of the antistatic film 300 is larger than the area A2 of the object 200, so the antistatic film 300 completely covers the contact surface 220 of the object 200. The film attaching component 120 may hold the antistatic film 300 at its two opposite ends, and the material properties of the antistatic film 300 help reduce the formation of gap defects between the antistatic film 300 and the object 200. The antistatic film 300 has a lower surface 320 relative to its upper surface 310, and a second defect 312 may exist between the lower surface 320 of the antistatic film 300 and the contact surface 220 of the object 200, wherein the defect 312 is visible to the camera 140, and preferably visible to the camera 140 and detectable to the ultrasonic detector 150. In the embodiment, the second defect 312 can be the bubble defect. Although designs of way of disposing the antistatic film 300 on the contact surface 220 of the object 200 may reduce the occurrence of the second defect 312, or even eliminate the second defect 312 between the lower surface 320 of the antistatic film 300 and the contact surface 220 of the object 200, it is still unavoidable that a small number of second defects 312 may remain between the antistatic film 300 and the object 200 due to general film disposing techniques. At this point, a camera 140 positioned above the antistatic film 300 may be used to observe the second defect 312 located between the lower surface 320 of the antistatic film 300 and the contact surface 220 of the object 200. Since the antistatic film 300 itself is transparent or translucent, the camera 140 positioned above the antistatic film 300 may capture images of the second defect 312 below the antistatic film 300. As a result, the second defect 312 will not be mistakenly identified as a first defect 212 that occurs during the stacking of the layer structures 210.

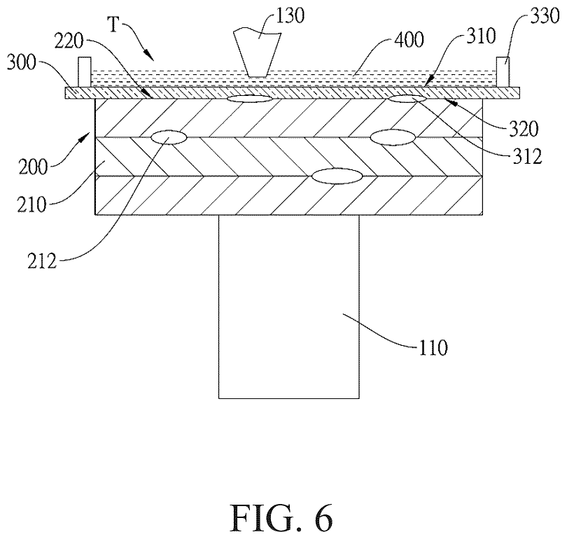

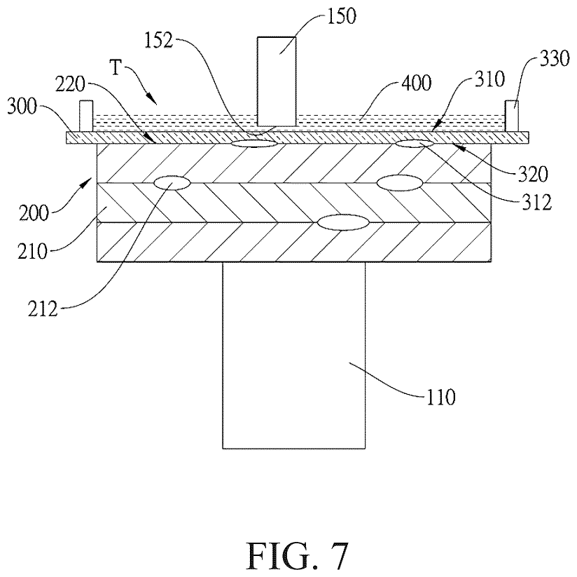

In FIGS. 6 and 7, the antistatic film 300 has an upper surface 310 facing away from the object 200 and a lower surface 320 opposite to the upper surface 310. The detection method includes applying a conductive liquid 400 onto the upper surface 310 of the antistatic film 300 using a liquid infusion component 130 positioned above the antistatic film 300. The conductive liquid 400 is a liquid with excellent ultrasonic transmission properties, which helps the ultrasonic detector 150 obtain clear images during subsequent detection. Additionally, the upper surface 310 of the antistatic film 300 includes a hollow annular barrier 330, which defines a detection area T. The conductive liquid 400 may be physically confined within the detection area T to prevent the conductive liquid 400 from flowing into undesired regions. After the conductive liquid 400 is applied, the ultrasonic detector 150 positioned above the object may be placed into the conductive liquid 400 and detects the first defect 212 in the object 200. The end 152 of the ultrasonic detector 150 is covered by the conductive liquid 400 and is separated from the upper surface 310 of the antistatic film 300. In other words, the ultrasonic detector 150 does not make direct contact with the antistatic film 300, such that no downward pressure is applied to the object 200, which could otherwise compress the contact surface 220 of the object 200.

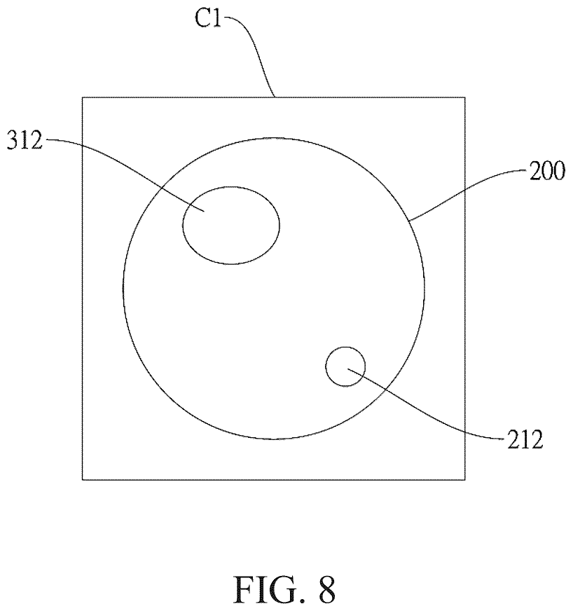

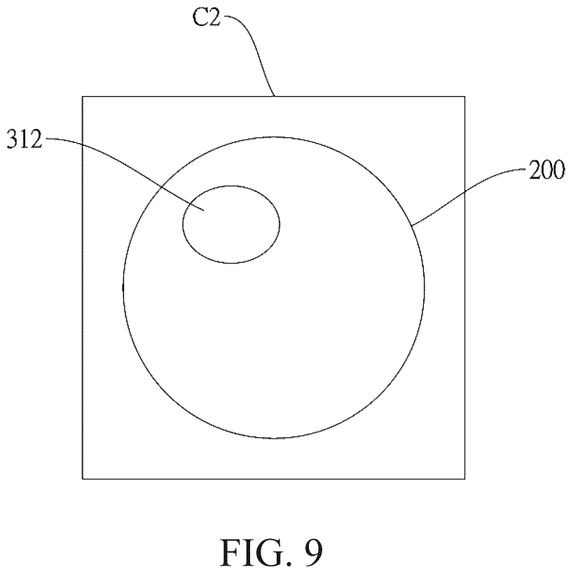

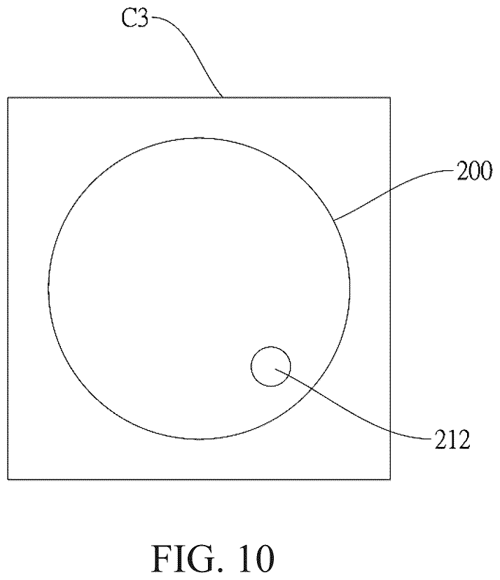

Referring to FIGS. 8 to 10, FIG. 8 illustrates a schematic diagram of a first detection image C1 according to an embodiment of the present disclosure, FIG. 9 illustrates a schematic diagram of a second detection image C2 according to an embodiment of the present disclosure, and FIG. 10 illustrates a schematic diagram of a third detection image C3 according to an embodiment of the present disclosure. In the embodiment, the first defect 212 and the second defect 312 are bubble defects. In FIGS. 8 to 10, the detection method further includes scanning the contact surface of the object below the antistatic film 300 with the ultrasonic detector 150 in a reciprocating manner to generate a first detection image C1, which may include the first defect 212 or both the first defect 212 and second defect 312. Additionally, a camera 140 may generate a second detection image C2 that includes the second defect 312. The second defect 312 is located between the lower surface 320 that is opposite to the upper surface 310 of the antistatic film 300 and the contact surface 220 of the object 200. The first detection image C1 generated by the ultrasonic detector 150 may be transmitted to the determining module 160. The second detection image C2 generated by the camera 140 may also be transmitted to the determining module 160, which stores the first detection image C1.

In some embodiments, the determining module 160 may subtract the second detection image C2 from the first detection image C1 to obtain a third detection image C3, and the determining module 160 may determine the shape and position of the first defect 212 based on the third detection image C3. Specifically, when the resolution of the ultrasonic detector 150 is insufficient, the first detection image C1 may include both the first defect 212 within the object 200 and the second defect 312 between the object 200 and the antistatic film 300, as shown in FIG. 8. The determining module 160 may obtain information about the second defect 312 from the second detection image C2 provided by the camera 140, as shown in FIG. 9, and subtract the data of the second detection image C2 from the data of the first detection image C1. As a result, the determining module 160 generates a third detection image C3 that removes the information of the second defect 312, as shown in FIG. 10. By analyzing the third detection image C3, operators can determine the shape and position of the first defect 212 within the object 200.

In summary, the ultrasonic detector 150 of the defect detection device 100 of wafer and chip packaging may transmit the first detection image C1 to the determining module 160, allowing the determining module 160 to determine the shape and position of the first defect 212 in the object 200 by analyzing both of the first detection image Cl and second detection image C2. After obtaining the shape and position of the first defect 212 in the object 200, the defect detection device 100 of wafer and chip packaging may immediately notify the operator of the shape and position of the first defect 212. During subsequent processing of the object 200, the portion corresponding to the first defect 212 may be discarded. Alternatively, if the number of first defects 212 is too high or the defect area is too large, the plurality of layer structures 210 of the object 200 may be rebounded. The defect detection device 100 and detection method of wafer and chip packaging disclosed in this disclosure may address the issue of conventional chip or wafer stacking structures being unable to come into contact with detection liquids (such as conductive liquid 400) and may also improve the problem of incomplete cleaning of chip or wafer stacking structures after contact with detection liquids. Therefore, by using the defect detection device 100 and detection method of wafer and chip packaging disclosed in this disclosure, the product yield of subsequent applications can be effectively improved. This includes improving the yield of multi-layer stacked structures such as wafer-on-wafer (WoW) structures, chip-on-wafer (CoW) structures, or substrate-on-substrate structures. Additionally, the defect detection device 100 and detection method of wafer and chip packaging disclosed in this disclosure also improve the problems of some stacked wafer or chip structures cannot come into contact with detection liquids, or the drying and cleaning process after contact with the detection liquid may damage the stacked structure or introduce other impurities into the wafer or chip so that the complexity and duration of the bubble detection process for wafer and chip packaging is reduced.

The foregoing outlines several features of the embodiments, enabling those skilled in the art to better understand the aspects of the present disclosure. It should be understood by those skilled in the art that this disclosure can be readily used as a basis for designing or modifying other processes and structures to achieve the same objectives and/or advantages as described in the embodiments herein. Those skilled in the art should also recognize that equivalent structures may be implemented without departing from the spirit and scope of this disclosure, and various modifications, substitutions, and changes may be made within the scope of this disclosure.

1. A detecting method of defects of wafer and chip packaging, used to detect a first defect in an object, comprising:
disposing a transparent or translucent antistatic film on a contact surface of the object, wherein an area of the antistatic film is larger than an area of the object, so that the antistatic film completely covers the contact surface of the object, the object has a plurality of layer structures, and the plurality of layer structures has the first defect between two adjacent upper-and lower-layer structures, wherein the first defect is detectable to an ultrasonic detector;
applying a conductive liquid on an upper surface of the antistatic film that is facing away from the object; and
placing the ultrasonic detector into the conductive liquid to detect the first defect located in the object, wherein an end portion of the ultrasonic detector is covered by the conductive liquid and is separated from the upper surface of the antistatic film.

2. The detecting method of claim 1, wherein detecting the first defect in the object further comprises:
scanning the contact surface of the object located below the antistatic film with the ultrasonic detector in a reciprocating manner to generate a first detection image that includes the first defect; and
transmitting the first detection image to a determining module.

3. The detecting method of claim 1, wherein the first defect is a bubble defect, a dirty defect, a impurity defect or a crack defect.

4. The detecting method of claim 2, further comprising:
positioning a camera above the upper surface of the antistatic film;
using the camera to observe a second defect and generate a second detection image including the second defect, wherein the second defect is located between the lower surface of the antistatic film relative to the upper surface of the antistatic film and the contact surface of the object; and
transmitting the second detection image to the determining module that stores the first detection image.

5. The detecting method of claim 4, wherein the first defect is a first bubble defect and the second defect is a second bubble defect.

6. The detecting method of claim 4, further comprising:
the determining module subtracting the second detection image from the first detection image to obtain a third detection image, and the determining module determining shape and position of the first defect based on the third detection image, wherein the second defect is a defect visible to the camera and detectable to the ultrasonic detector.

7. The detecting method of claim 1, further comprising:
using a hollow annular barrier of the antistatic film to restrict the conductive liquid, so that the conductive liquid is confined within a detection area defined by the hollow annular barrier.

8. The detecting method of claim 1, wherein the object is a wafer-on-wafer structure, a chip-on-wafer structure, or a substrate-on-substrate structure.

9. A defect detection device of wafer and chip packaging, used to detect a first defect in an object, comprising:
a platform for supporting an object, wherein the object has a plurality of layer structures, and the first defect is located between two adjacent upper-and lower-layer structures and detectable to an ultrasonic detector;
a film attaching component disposed above the platform and used for placing a transparent or translucent antistatic film on a contact surface of the object, wherein an area of the antistatic film is larger than an area of the object, so that the antistatic film completely covers the contact surface of the object;
a liquid infusion component disposed above the antistatic film and used for applying a conductive liquid on an upper surface of the antistatic film that is facing away from the object; and
the ultrasonic detector disposed above the object and placed into the conductive liquid to detect the first defect in the object, wherein an end portion of the ultrasonic detector is covered with the conductive liquid and is separated from the upper surface of the antistatic film.

10. The defect detection device of claim 9, wherein the object is a wafer-on-wafer structure, a chip-on-wafer structure, or a substrate-on-substrate structure.

11. The defect detection device of claim 9, wherein the ultrasonic detector is further used to scan the contact surface of the object below the antistatic film in a reciprocating manner to generate a first detection image including the first defect.

12. The defect detection device of claim 9, wherein the first defect is a bubble defect, a dirty defect, a impurity defect or a crack defect.

13. The defect detection device of claim 11, further comprising:
a camera disposed above the antistatic film and used for observing a second defect to generate a second detection image that includes the second defect wherein the second defect is located between the lower surface of the antistatic film that is opposite to the upper surface, and the contact surface of the object; and
a determining module electrically coupled to the camera and the ultrasonic detector and used to receive the first detection image and the second detection image.

14. The defect detection device of claim 13, wherein the first defect is a first bubble defect and the second defect is a second bubble defect.

15. The defect detection device of claim 13, wherein the determining module is further used for subtracting the second detection image from the first detection image to obtain a third detection image, and the determining module determines shape and position of the first defect based on the third detection image, wherein the second defect is a defect visible to the camera and detectable to the ultrasonic detector.

16. The defect detection device of claim 9, wherein the antistatic film has a hollow annular barrier to restrict the conductive liquid, so that the conductive liquid is confined within a detection area defined by the hollow annular barrier.
